(19) United States
(12) Patent Application Publication
(10) Pub. No.: US 2012/0175247 A1
(43) Pub. Date: Jul. 12, 2012

(54) INTRMITTENT PULSE ELECTROLYSIS

(76) Inventor: Fletcher Darrel, Minneola, FL (US)

(21) Appl. No.: 13/346,643

(22) Filed: Jan. 9, 2012

Related U.S. Application Data
(60) Provisional application No. 61/430,719, filed on Jan. 7, 2011.

(51) Int. Cl. C25B 15/02; H03K 3/00; C25B 9/04

(52) U.S. Cl. 204/229.3; 204/229.4; 327/291

(57) ABSTRACT

A pulse generator includes a wave generator connected to a power source, the wave generator having an output signal; a de-multiplexer having a single input for receiving the output signal of the wave generator and splitting the signal into a plurality of channels carrying corresponding DeMux output signals; and a multiplexer electrically connected to each of the DeMux output signals and including means for alternately advancing or retarding the time interval between pulses of each the DeMux output signals and for combining at least two of the advanced or retarded output signals together and outputting the at least two advanced or retarded output signals as a single circuit output signal having a diverse pulse train. Pulse control means for controlling at least one of the pulse width and pulse amplitude of the circuit output signal is also provided.

### RELATED APPLICATION

This application claims the benefit of U.S. Provisional Application No. 61/430,719 filed Jan. 7, 2011 and entitled, Intermittent Pulse Electrolysis.

### FIELD OF THE INVENTION

The subject invention relates generally to an apparatus and method for decomposing chemical compounds by means of electrical energy and, more specifically to such an apparatus and method for obtaining the release of hydrogen and oxygen from water by means of delivering an intermittent pulsed signal to at least one electrolytic cell.

### BACKGROUND OF THE INVENTION

Numerous processes have been proposed for separating a water molecule into its elemental hydrogen and oxygen components. Electrolysis is one such process. In electrolysis, a potential difference is applied between an anode and a cathode in contact with an electrolytic conductor to produce an electric current through the electrolytic conductor.

In the conventional DC electrolysis of water, hydrogen is generated as a result of electron transfer from the cathode electrode to adsorbed hydrogen ions on the electrode surface. This electrolysis occurs when the applied voltage between the anode and the cathode exceeds the water decomposition voltage of about 1.6 V, the sum of the theoretical decomposition voltage of 1.23 V at room temperature and the overvoltage of about 0.4 V depending on electrode materials and other factors. DC electrolysis is a diffusion limited process and the current flow in water is determined by the diffusion coefficient of ions. It is therefore difficult to increase the input power for a constant volume electrochemical cell without reduction in electrolysis efficiency. More specifically, when the applied voltage is increased, the current increases so that hydrogen generation rate increases, but the efficiency compared with the ideal generation rate decreases from 40% at 2.2V to 8% at 12.6V. The decrease in efficiency can be explained because an electron with high energy can only reduce one hydrogen ion so that the difference between the applied voltage and the decomposition voltage is dissipated as heat. Since the current itself is also increased by increasing the applied voltage, electrons which are not used for hydrogen reduction are also dissipated as heat. In the case of DC power, the electric field is always present. The electrical double layer is also present and the diffusion layer always exists. The current flow is therefore determined by the diffusion of ions with a driving force of ion concentration difference. When the applied voltage is increased; the efficiency decreases. In the case of DC power, the power applicable for a certain volume of the electrolysis bath is therefore limited.

It has been demonstrated that when an ultra-short pulse voltage of less than several microseconds is applied to a water electrolysis bath, the voltage application is so fast neither the electric double layer nor the diffusion layer can be stably formed in the vicinity of the electrodes. This means that electrolysis occurs without forming the diffusion layer; it is also known that the time necessary for the formation of the stable electrical double layer is, on the order of several tens of milliseconds. This suggests that the stable electrical double layer is not formed during ultra-short pulse application. Since an electric field as high as 47V cm¹ can be applied without a formation of the stable electric double layer means that hydrogen ions can be moved faster than in conventional DC electrolysis. These different mechanisms that arise via ultra-short pulse application, leading to the absence of the diffusion layer and the stable electrical double layer, lead to the possibility of high capacity water electrolysis.

Moreover, it has been demonstrated that the delivery of a diverse pulse train comprised of varying pulse widths and/or pulse delays in the nano-second time domain results in electrolysis efficiency superior to that achievable with conventional DC electrolysis. A Pulse generator usually allows control of the pulse repetition rate, pulse width, pulse delay and pulse amplitude. More sophisticated pulse generators may allow control over the rise time and fall time of the pulses. A pulse generator's delay is measured with respect to an internal or external trigger. The pulse generator's rate may be determined by a frequency or period adjust (i.e., repetition rate).

Pulse generators may use digital techniques, analog techniques, or a combination of both techniques to form the output pulses. For example, the pulse repetition rate and duration may be digitally controlled but the pulse amplitude and rise and fall times may be determined by analog circuitry in the output stage of the pulse generator.

### SUMMARY OF THE INVENTION

The present invention enables a fuel comprised of hydrogen and/or oxygen gases to be generated by electrolysis of water at such a rate that it can enhance performance of an internal combustion engine. It achieves this result by use of a novel pulse generator in conjunction with at least one electrolytic cell. According to the present invention, there is provided a pulse generator comprising four primary components, namely, 1) a wave generator connected to a power source, the wave generator having an output signal, 2) a de multiplexer (DeMux) having a single input for receiving, the output signal of the wave generator and splitting the signal into a plurality of channels carrying corresponding DeMux output signals, 3) a multiplexer (Mux) electrically connected to each of the channel outputs and including means for adjusting the time interval (advance/retard) between pulses of each channel output signal and combining any or all of them together and outputting them on a single channel having a diverse pulse train, and 4) pulse control means for controlling the pulse width and height (amplitude) of the circuit output signal.

Although the above channel multiplexing only combines timing events of the channels and not the actual output voltages or currents, other embodiments of the subject intermittent pulse generator further include means for producing diverse pulse widths as well.

The output pulses of the above described intermittent pulse generator are then supplied to the anode of an electrolytic cell which, in consort with at least one cathode and an electrolytic fluid produces a chemical reaction that resulting in the production of free oxygen and hydrogen ions. Either or both may be introduced into the combustion situs of an engine to enhance burning of the hydrocarbon, fuels to improve the efficiency and cleanliness of the burn.

There has thus been outlined, rather broadly, the more important components and features of the invention in order that the detailed description thereof that follows may be better understood, and in order that the present contribution to the art may be better appreciated. There are, of course, additional features of the invention that will be described hereinafter and which will form the subject matter of the claims appended hereto. In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods and systems for carrying out the several purposes of the present invention.

For a better understanding of the invention, its advantages and the specific objects attained by its uses, reference should be had to the accompanying drawings and descriptive matter in which there is illustrated a preferred embodiment of the invention.

### BRIEF DESCRIPTION OF THE DRAWINGS

The invention will be better understood and objects other than those set forth above will become apparent when consideration is given to the following detailed description thereof. Such description makes reference to the annexed drawings wherein:

FIG. 1 is a block diagram of the pulse generator of subject invention; and

FIG. 2A-2C illustrate wave forms of the various modes of operation of the subject pulse generator.

### DETAILED DESCRIPTION OF THE PREFERRED EMBODIMENT

Pulse generators are generally single-channel providing one frequency, delay, width and output. To produce multiple pulses, these simple pulse generators are typically ganged in series or in parallel. The subject pulse generator is designed to multiplex the timing of several channels onto one channel in order to trigger or gate the same device multiple times using a diverse pulse train.

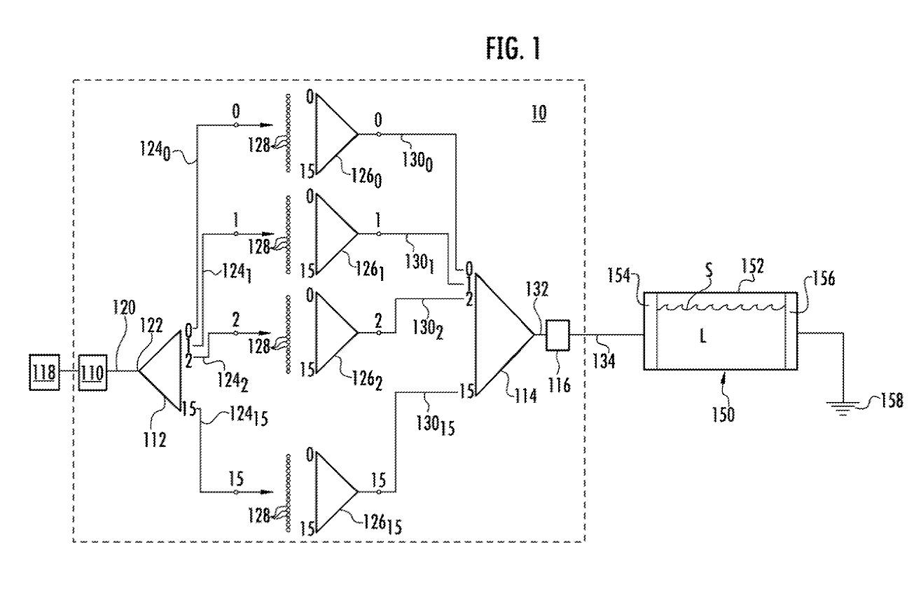

More specifically, according to the present invention, and referring to FIG. 1, there is provided a pulse generator designated generally by reference numeral 10 comprising four primary components, namely, 1) a wave generator 110, 2) a de multiplexer (“DeMux”) 112, 3) a multiplexer (“Mux”) 114, and 4) pulse control means 116, all electrically connected in series.

Wave generator 110 is connected to a power source 118 and, when activated, produces an output signal 120. DeMux 112 has a single input 122 for receiving the output signal 120 of the wave generator 110 and splitting signal 120 into a plurality of sequential DeMux output signals 124₀₋ₙ each of which is referred to as a “channel”. In the example illustrated, sixteen DeMux output signals 0-15 are depicted, but it should be readily appreciated that the number of DeMux channels into which the original signal is split depends upon the specific DeMux chip 112 selected by the user. Mux 114 includes a plurality of Mux inputs 126₀₋ₙ; one corresponding to each DeMux output signal 124₀₋ₙ. Each Mux input 126₀₋ₙ includes signal adjustment means for adjusting the time interval (advance or retard) between each bit 128 of each DeMux output signal 124₀₋ₙ. In a first embodiment, each Mux input 126₀₋ₙ includes sixteen manually selectable timing variables. The default timing for each Mux input 126₀₋ₙ is set at 7, for example, and the user can manually select one of the remaining fifteen variables to advance or retard the timing. Once the timing interval of each channel has been selected, the corresponding Mux output signals 130₀₋ₙ are sequentially fed into the Mux chip which sums them together and outputs them in the form of a single output channel carrying a Mux output signal 132 comprised of a selectably uniform or diverse pulse train. Mux output signal 132 is then fed into pulse control means 116 such as a pico-second triggered chip that imparts a controlled pulse width and height (amplitude) to Mux output signal 132 resulting in circuit output signal 134 characterized by a controlled pulse width and height as well as a uniform or diverse pulse train. The resolution of the circuit output signal 134 can be adjusted to one signal per RPM, 4, 8, or 16 signals per RPM, based upon the required resolution of the apparatus to be controlled (i.e., a motor or electrolytic cell).

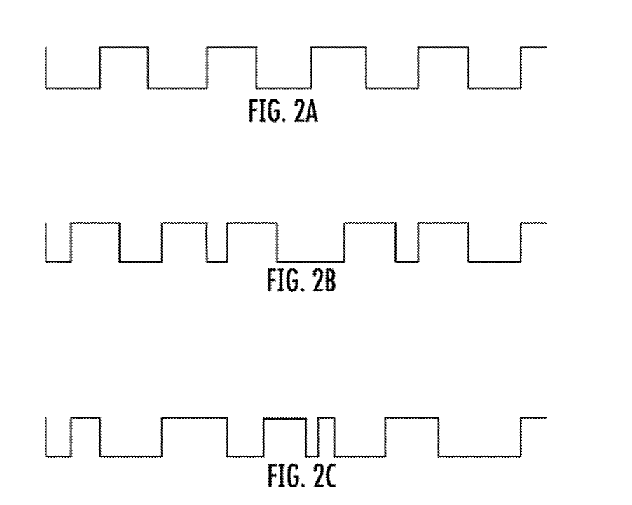

When either all of the Mux inputs 126₀₋ₙ are set at the same pulse width variable, the resulting Mux output signal 132 appears as in FIG. 2A with uniform width's (i.e. time delays) between each pulse. However, any or all of Mux inputs 126₀₋ₙ may be set to provide for a longer or shorter delay time (i.e., to advance or retard the delay interval) between pulses. FIG. 2B illustrates a diverse pulse train having a plurality of different delay times. Although the above channel multiplexing only combines timing events of the channels and not the actual output voltages or currents, other embodiments of the subject intermittent pulse generator further include means for producing diverse pulse widths as well such as the pulse train illustrated in FIG. 2C.

The output pulses that comprise circuit output signal 134 of the above described intermittent pulse generator 10 are then supplied to electrolytic cell 150. A simple electrolytic cell 150 is comprised of housing 152 inside of which is an anode 154, a cathode 156 connected to an external ground 158, and an electrolyte L in which anode 154 and cathode 156 are immersed. The electrolyte is usually a solution of water or other solvents in which ions are dissolved. Many molten salts and hydroxides are electrolytic conductors but usually the conductor is a solution of a substance which dissociates in the solution to form ions. The term “electrolyte” will be used herein to refer to a substance which dissociates into ions, at least to some extent, when dissolved in a suitable solvent.

Electrolytic devices that decompose water to liberate its component elements, hydrogen and oxygen, are well known in the art. Commercially, such electrolytic cells have been used with varying degrees of success to increase the efficiency of combustion engines and are also used for bench top production of Hydrogen and Oxygen for lab or commercial use. The mixture of the liberated hydrogen with a hydrocarbon fuel and air in a combustion engine has many benefits among which are enriching and improving the charge, promoting combustion, producing less toxic combustion products, increasing power, increasing the efficiency of the engine, and/or economizing on fuel.

The energy required to cause the ions to migrate to the electrodes, and the energy to cause the change in ionic state, is provided by the external source of pulsed electrical potential. Only with an external electrical potential (i.e. voltage) of the correct polarity and large enough magnitude can an electrolytic cell decompose a normally stable, or inert chemical compound in the solution. However, a serious drawback of many electrolytic cells of the prior art is that they are incapable of: producing hydrogen at a rate sufficient to maintain a constant flow to the internal combustion engines. A variety of electrolytic cell designs have been created in an effort to increase the rate of electrolysis. The subject intermittent pulse generator 10 produces a diverse pulse train which when used to drive an electrolytic cell liberates Hydrogen and Oxygen at rates more than sufficient to improve engine performance as discussed in greater detail below.

In the case of water electrolysis using the above described ultra-short diverse pulse train, the bath acts as a quasi-capacitor since the pulse width is too short for ions in the bath to cause a current. This is verified since multiple tested solutions of distilled, tap water and a combination of distilled/tap water with KOH, sodium bicarbonate, salt, and chlorine were tried, with approximately the same results. The water bath is not a real capacitor since the potential difference between the anode and cathode directly affect the hydrogen ions and high voltage does not remain as in the case of conventional capacitors. Since the application of the pulsed voltage is already terminated, this current flow may not be due to electron transfer to hydrogen ions but ion transport in the bath, thus compensating the lack of hydrogen ions in the vicinity of the cathode electrode.

### Example 1

### Hydrogen vs. Hydrogen and Oxygen Fed into Vehicle Equipped with 7.3 Liter Duramax Diesel Engine

An electrolytic fluid F is interposed within housing 152 of electrolytic cell 150 in sufficient volume to substantially cover the surfaces of anode 154 and cathode 156. Typically, the electrolytic fluid may be either water, potassium hydroxide or a similar compound capable of generating free oxygen and hydrogen ions as a result of an electrolytic reaction. The volume of fluid F will generally not entirely fill housing space 18 and a space S will typically be left at the top portion thereof. The subject intermittent pulse generator 10 is set to deliver to the electrolytic cell 150 a train of ultra-short pulses, the rate of which is limited only by available technology, with 0 to 16 different time delay settings per each sixteen channel cycle. In a rotational motor with 16 active channels per crank rotation equals a timing baseline of 22.5 degrees per crank rotation. Sixteen channels times 16 MUX channels equals 256 timing points per rotation, which provides 11.5 degrees of advance or retard per active channel. The Hydrogen and Oxygen liberated from water were then fed into a 7.3 liter Duramax diesel engine at different flow rates to determine the optimal rate for maximizing Torque production. The test vehicle had a single hose connection at the air intake box. All gases where ran thru a separate water bubbler for the mixing, and safety aspects.

Injection of liberated Hydrogen only: A truck equipped with a 7.3 liter Duramax diesel engine was ran under a steady state condition of 1700 rpms under a 5% load “approximately 50 mph”, where the Hydrogen level was increased at a rate of 0.5 liters a minute, every 45-seconds, as regulated using a Victor 0-8 LPM dial regulator gauge. This extended load testing went from 0.5 to 6 liters a Minute of usage, in an effort to discover the optimal Torque production for the 7.3 liter Duramax diesel engine.

Injection of liberated Hydrogen and Oxygen mix (2 parts Hydrogen to 1 part Oxygen): The truck was run under a steady state condition of 1700 rpms under a 5% load “approximately 50 mph”, where the Hydrogen and Oxygen input levels were each increased at a rate of 0.5 Liters a minute, every 45 seconds, as regulated using two Victor 0-8 LPM dial regulator gauges; one for Hydrogen and one for Oxygen. This extended load testing went from 0.5 to 6 liters a minute.

Results: Between 2-2.5 liters a minute of Hydrogen and Oxygen, resulted in an optimal amount, about a 25% increase over just Hydrogen, at the same measured amount, which was shown from extended Dyno run graphs, which would achieve a peak torque and then drop off, with the gas level being increased. A final test run was performed at a rate of 2.2 liters a minute of combined Hydrogen and Oxygen which measured a final peak pull of 230.8 HP and 782.8 Ft/Lbs on the Mustang Dynamometer, which supports a gain of approximately 9% over initial Horsepower and Torque.

Observations: At the optimized 2.2 LPM of Hydrogen and Oxygen at a 5% steady state load and the rpm's maintained at 1700, the truck went from 50 mph to over 73 mph at the same rpm, due to the increase of Torque. The initial peak HP and TQ test run, blew heavy black smoke, however with the optimal 2.2 LPM of Hydrogen and Oxygen, the look and smell of the exhaust was remarkably clean for a diesel exhaust system. The Exhaust Gas Temperature “EGT” measured a decrease of approximately 50 degrees Fahrenheit at the optimal 2.2 LPM.

### Example 2

### Hydrogen vs. Hydrogen and Oxygen Mix Fed into Vehicle Equipped with 6.7 Liter Cummins Diesel Engine

Using the same setup and protocol described above, the optimal flow rates of Hydrogen and then a Hydrogen/Oxygen mixture into a 2007 Dodge 3500 truck equipped with a 6.7 liter Cummins diesel were determined. Engine performance without the subject apparatus was measured at 350 HP and 650 Ft/Lbs of torque on the initial run for testing of Peak HP and Torque on the Mustang Dynamometer, which is consistent with the published results for this vehicle engine, make and model.

Injection of liberated Hydrogen only: The tuck was ran under a steady state condition; @ 1500 rpms under a 5% load “approximately 50 mph”, where the Hydrogen level was increased at a rate of 0.5 Liters a minute, every 45-seconds, using a Victor 0-8 LPM dial regulator gauge. This extended load testing went from 0.5 to 6 liters a minute.

Injection of liberated Hydrogen and Oxygen mix (2 parts Hydrogen to 1 part Oxygen): The truck was run under a steady state condition; @ 1500 rpms under a 5% load “approximately 50 mph”, where the Hydrogen and Oxygen level wee increased at a rate of 0.5 Liters a minute, every 45 seconds at a ratio of 2 parts Hydrogen to 1 part Oxygen, every 45-seconds, using two Victor 0-8 LPM dial regulator gauges. This extended load testing went from 0.5 to 6 liters a minute.

Results: Between 2-2.5 liters a minute of Hydrogen and Oxygen was the optimal flow rate achieving a peak torque and then dropping off a flow rates fell above or below this level. A final test run at a rate of 2.2 liters a minute of combined Hydrogen and Oxygen was conducted and produced a final peak pull of 384.2 HP and 714.8 Ft/Lbs on the Mustang Dynamometer, which supports a gain of approximately 10% over initial Horsepower and Torque. Tests with mixed Hydrogen and Oxygen resulted in a performance increase of about 25% over Hydrogen alone, at the same measured flow rates.

Observations: The Exhaust Gas Temperature “EGT” measured a decrease of approximately 80 degrees Fahrenheit at the optimal 2.2 LPM.

### CONCLUSIONS

Use of the subject intermittent pulse generator 10 in combination with an electrolytic cell as described above produced a very consistent 10% increase in horsepower and torque for the two diesel engines. This equates to, approximately a 22%-23% increase in fuel economy.

In the case of pulse power, the hydrogen generation rate is increased as the peak voltage is decreased (i.e., the narrower the pulse the more efficient the production). It should be noted, however, that the hydrogen generation rate increases as a function of the input power. This behavior is quite different from the case of DC electrolysis. When the pulse frequency is increased, the efficiency was not decreased in the case of high peak voltages, and was increased in the case of low peak voltages. This behavior is contrary to the case of DC power. This increase of the efficiency for the case of low peak voltage may be because the energy dissipation is decreased since each electron has lower energy and the pulse waveform is sharper for low peak voltages. For these reasons, power can be efficiently consumed for electrolysis; this fact implies that the ultra-short power electrolysis is a promising method in which the power application can be increased even with an increase in electrolysis efficiency.

In the case of ultra-short pulsed power, the electric field is applied for only a very short time; which is much shorter than the time necessary for the formation of the constant electric double layer. By the application of the ultra-short pulse, a large potential difference is created which is very similar to a capacitor. This large potential difference excites the hydrogen ions breaking the covalent bond allowing hydrogen generation. This is done without production of heat as this process directly affects the covalent bond without the material reactance that produces heat.

From the above considerations, it can be concluded that the electrolysis mechanism for ultra-short pulse power with a diverse pulse train is very different from that of DC electrolysis. DC electrolysis is based on electrical double layer formation and is a diffusion-limited process, while ultra-short pulse power electrolysis is based on the strong electric field application and the electron transfer limited process. This difference seems to be very important for the practical application of ultra-short power electrolysis since the electrolysis power can be increased without decreasing the efficiency.

In addition to finding application in enhanced electrolysis, it should be appreciated that the intermittent pulse generator of the subject invention has, other applications as well. For instance, the subject pulse generator may also used to drive devices such as switches, lasers and optical components, modulators, intensifiers and resistive loads. It may also be used to control timing on an engine, a magnetic motor, or a pulsed driver circuit. In its current setup you can adjust the resolution to one signal per RPM, 4, 8, or 16 signals per RPM, based upon the required resolution for a motor or engine.

The subject apparatus meets needs for extremely complex timing sequences. These timing requirements range from controls and diagnostics to signal quality monitoring and data acquisition. A wide range of signal filters, timing pulses, digital delay generation and cabling links can be accomplished with the subject intermittent pulse circuit. With its timing capabilities, this is akin to a PLC (programmable logic controller) with precise programmed timing.

Although the present invention has been described with reference to the particular embodiments herein set forth, it is understood that the present disclosure has been made only by way of example and that numerous changes in details of construction may be resorted to without departing from the spirit and scope of the invention. Thus, the scope of the invention should not be limited by the foregoing specifications, but rather only by the scope of the claims appended hereto.

What is claimed as being new, useful and desired to be protected by Letters Patent of the United States is as follows:

1. A pulse generator comprising:
a. a wave generator connected to a power source, the wave generator having an output signal;
b. a de-multiplexer having a single input for receiving said output signal of said wave generator and splitting said signal into a plurality of channels carrying corresponding DeMux output signals; and
c. a multiplexer electrically connected to each of said DeMux output signals and including means for alternately advancing or retarding the time interval between pulses of each said DeMux output signal and for combining at least two of said advanced or retarded output signals together and outputting said at least two advanced or retarded output signals as a single circuit output signal having a diverse pulse train.

2. The pulse generator of claim 1, further including pulse control means for controlling at least one of the pulse width and pulse amplitude of the circuit output signal.

3. The pulse generator of claim 2, wherein said pulse control means is a pico-second triggered chip.

4. The pulse generator of claim 1, wherein the resolution of the circuit output signal is selectively adjustable to one, four, eight, or sixteen signals per RPM, based upon the required resolution of the apparatus to be controlled.

5. The pulse generator of claim 2, wherein the resolution of the circuit output signal is selectively adjustable to one, four, eight, or sixteen signals per RPM, based upon the required resolution of the apparatus to be controlled.

6. The pulse generator of claim 3, wherein the resolution of the circuit output signal is selectively adjustable to one, four, eight, or sixteen signals per RPM, based upon the required resolution of the apparatus to be controlled.

7. The pulse generator of claim 1, wherein said single circuit output signal is electrically coupled to an electrolytic cell.

8. The pulse generator of claim 2, wherein said single circuit output signal is electrically coupled to an electrolytic cell.

9. The pulse generator of claim 3, wherein said single circuit output signal is electrically coupled to an electrolytic cell.

10. The pulse generator of claim 4, wherein said single circuit output signal is electrically coupled to an electrolytic cell.

11. The pulse generator of claim 5, wherein said single circuit output signal is electrically coupled to an electrolytic cell.

12. The pulse generator of claim 6, wherein said single circuit output signal is electrically coupled to an electrolytic cell.

13. The pulse generator of claim 7, wherein said single circuit output signal is electrically coupled to an electrolytic cell.

14. An apparatus for performing intermittent pulse electrolysis, comprising
a. a wave generator connected to a power source, the wave generator having an output signal;
b. a de-multiplexer having a single input for receiving said output signal of said wave generator and splitting said signal into a plurality of channels carrying corresponding DeMux output signals;
c. a multiplexer electrically connected to each of said DeMux output signals and including means for alternately advancing or retarding the time interval between pulses of each said DeMux output signal and for combining at least two of said advanced or retarded output signals together and outputting said at least two advanced or retarded output signals as a single circuit output signal having a diverse pulse train; and
d. an electrolytic cell comprising an anode, a cathode and an electrolyte all within a housing; said anode and said cathode being immersed in said electrolyte; said anode being electrically connected to said circuit output signal; said cathode being connected to an external ground;
whereby the ultra-short diverse pulse train drives an electrolysis reaction within said electrolytic cell.
